(19) United States
(12) Patent Application Publication
(10) Pub. No.: US 2008/0135092 A1
(43) Pub. Date: Jun. 12, 2008

(54) Solar roof tiles with heat exchange

(75) Inventor: Eugenia M. Corrales, Los Altos, CA (US)

Correspondence Address: MORRISON & FOERSTER LLP, 755 PAGE MILL RD, PALO ALTO, CA, 94304-1018, US

(73) Assignee: Sunmodular, Inc., Los Altos, CA (US)

(21) Appl. No.: 11/804,657

(22) Filed: May 18, 2007

Related U.S. Application Data
(60) Provisional application No. 60/874,313, filed on Dec. 11, 2006.

(51) Int. Cl. H01L 31/024; H01L 31/0203

(52) U.S. Cl. 136/256; 136/259

(57) ABSTRACT

A photovoltaic tile with photovoltaic cell and a heat sink. The heat sink is attached on a side of the cell opposite to the light-receiving side of the photovoltaic cell and can remove heat caused by light absorbed by the photovoltaic cell but not converted to electricity as well as heat generated by electrical resistance. A photovoltaic tile formed of such cells can exhibit greater energy conversion efficiency as a result of the ability to dissipate the heat. The tiles can be arranged on a roof to protect the roof structure and generate electricity. Photovoltaic tiles comprising interlocking mechanical and electrical connections for ease of installation are described. Methods of making photovoltaic tiles involve e.g. laminating a heat sink to a photovoltaic cell and/or injection molding.

### CROSS REFERENCE TO RELATED APPLICATIONS

This application claims priority benefit of U.S. Provisional Application No. 60/874,313, entitled “Modular Solar Roof Tiles And Solar Panels With Heat Exchange” filed Dec. 11, 2006, which is incorporated by reference in its entirety herein as if it was put forth in full below.

### BACKGROUND OF THE INVENTION

Solar energy is a renewable energy source that has gained significant worldwide popularity due to the recognized limitations of fossil fuels and safety concerns of nuclear fuels. The photovoltaic (PV) solar energy demand has grown at least 25% per annum over the past 15 years. Worldwide photovoltaic installations increased by 1460 MW (Megawatt) in 2005, up from 1,086 MW installed during the previous year (representing a 34% yearly increase) and compared to 21 MW in 1985.

Growth in the field of solar energy has focused on solar modules fixed on top of an existing roof. Rooftops provide direct exposure of solar radiation to a solar cell and structural support for photovoltaic devices. Despite increased growth, the widespread use of conventional roof-mounted solar modules has been limited by their difficulty and cost of installation, lack of aesthetic appeal, and especially their low conversion efficiency.

Many conventional roof-mounted solar modules are constructed largely of glass enclosures designed to protect the fragile silicon solar cells. These modules are complex systems comprising separate mechanical and electrical interconnections that are then mounted into existing rooftops, requiring significant installation time and skill. Additionally, because existing modules do not provide weather protection to roof tops, homeowners are subjected to material and labor costs for both the modules and the protective roofing material to which they are mounted. Modules are also invasive in the aesthetics of homes and commercial buildings, resulting in limited use. A few manufacturers have fabricated more aesthetically pleasing and less obstructive solutions, but the systems are not price competitive largely due to installation difficulties and poor total area efficiency. Lower module efficiency levels are correlated to higher photovoltaic system costs because a greater module area is required for a given energy demand.

The efficiency of converting light into electricity for a typical crystalline-silicon roof-mounted solar cell is approximately 13%. Some systems have seen efficiency increases (up to 18-20%) by modifications such as the use of anti-reflective glass on the cell surface to decrease optical reflection, use of textured glass on the cell surface to increase light trapping, and the use of improved materials like thin film silicon or germanium alloy. Despite these improvements, solar cell conversion efficiency remains limited, in part, by high solar cell temperatures. The efficiency of a photovoltaic device decreases as the temperature increases. Part of the energy radiated onto the cell is converted to heat, which limits the electrical energy output and overall conversion efficiency of the cell. Fabrication of a system capable of removing heat from the photovoltaic cell would greatly increase total efficiency.

There is significant interest in and need for a photovoltaic tiles that addresses the above problems.

### BRIEF SUMMARY OF THE INVENTION

Described herein are various solar roof tiles that produce energy from the sun's radiation as well as various methods employed in fabrication of those solar tiles. Some of the tiles have increased efficiency in converting solar energy to electricity, are aesthetically attractive, and well suited for installation on unfinished rooftops. Some tiles minimize or prevent weather from reaching the underlying materials of a rooftop and together form a finished roof of a house. Some of the tiles are configured for attachment directly to battens or purlins for ease of installation.

In one instance, the photovoltaic tile has a photovoltaic cell, a housing adapted to mount on a rooftop and retain the photovoltaic cell while exposing light-receiving surfaces of the photovoltaic cell along a first surface of the housing, and a heat sink in thermal communication with an unexposed surface of said photovoltaic cell. The heat sink has a base positioned substantially parallel to the unexposed surface, and a plurality of fins attached to said base positioned substantially parallel to each other. The base has a thickness between 0.05″ and 0.5″; and the fins each independently have a height between 0.25″ and 7″, a center to center spacing between 0.05″ and 1″, a width between 0.001″ and 0.25″, and where the center to center spacing is sufficient to provide a channel between said fins for cooling air to enter.

In another instance, the photovoltaic tile has a thermal interface layer between the heat sink and the unexposed surface to improve heat dissipation.

In another instance, the heat sink has a length, thickness, fin height, fin spacing and fin width to maintain the photovoltaic cell at a temperature below about 150° F. in ambient air at a temperature of 70° F.

In another instance, the photovoltaic tile has an overhang along said first surface of said housing substantially parallel to a ridgeline of the rooftop.

In another instance, the photovoltaic tile has an overhang along said first surface of said housing substantially perpendicular to a ridgeline of the rooftop.

In another instance, the plurality of fins is positioned in a direction substantially parallel to a ridgeline of the rooftop.

In another instance, the plurality of fins is positioned in a direction substantially perpendicular to a ridgeline of the rooftop.

In another instance, the heat sink is constructed of extruded aluminum.

In another instance, the heat sink is constructed of black anodized aluminum.

In another instance, the base is constructed of a conductive polymer. In another instance the conductive polymer is an elastomer.

In another instance, the fins are discontinuous along a long axis of said base to form air escape and entry channels. In another instance, the channels are herringbone shape.

In another instance, the base has a thickness between 0.1″ and 0.25″; and the fins each independently have a height between 0.75″ and 5″, a center to center spacing between 0.2″ and 0.5″, and a width between 0.007″ and 0.1″. In another instance, the photovoltaic tile has a thermal interface layer between the heat sink and the unexposed surface to improve heat dissipation. In another instance, the plurality of fins is positioned in a direction substantially perpendicular to a ridgeline of the rooftop. In another instance, the heat sink is constructed of extruded aluminum.

In another instance, the photovoltaic tile has a thickness between 0.1″ and 0.2″; and the fins each independently have a height between 0.9″ and 2″, a center to center spacing between 0.3.″ and 0.4″, and a width between 0.02″ and 0.05″. In another instance, the photovoltaic tile has a thermal interface layer between the heat sink and said unexposed surface to improve heat dissipation. In another instance, the plurality of fins is positioned in a direction substantially perpendicular to a ridgeline of the rooftop. In another instance, the heat sink is constructed of extruded aluminum.

### BRIEF DESCRIPTION OF THE DRAWINGS

FIG. 1 is a perspective view of a photovoltaic tile with a heat sink.

FIG. 2A is a partial cross-sectional view of a photovoltaic tile with a heat sink containing fins.

FIG. 2B is a partial cross-sectional view of a photovoltaic tile with a heat sink containing frustum cones.

FIG. 3 is a top view of an array of overlapping tiles.

FIG. 4 is a cross-sectional view of an array of overlapping tiles on a rooftop.

FIG. 5A is a perspective view of an interlocking photovoltaic tile with a heat sink.

FIG. 5B is a partial perspective view of photovoltaic tiles with various mechanical and electrical configurations.

FIG. 5C is a side view of an additional variation of an interlocking photovoltaic tile.

FIG. 5D is a perspective view of an additional variation of an interlocking photovoltaic tile.

FIG. 6 is a top view and side view of an interlocking roof tile comprising a thin photovoltaic film.

FIG. 7 is a perspective view of interlocking shaped tiles each comprising a thin film.

FIG. 8A-1 is a cross-sectional view of an upper jig and a lower jig used to attach photovoltaic cell(s) to a heat sink.

FIG. 8A-2 is a bottom view of an upper jig.

FIG. 8B is the view shown in FIG. 8A-1 with a photovoltaic cells and a heat sink.

FIGS. 8C is the view shown in FIG. 8B with an interface layer.

FIG. 8D illustrates the apparatus shown in FIG. 8C where the upper jig and lower jig are compressed.

FIG. 8E shows photovoltaic cell(s) attached to a heat sink by the described process.

FIG. 8F is a cross-sectional view of an upper jig and a lower jig used to attach photovoltaic cell(s) to a heat sink containing frustum cones.

FIG. 8G shows photovoltaic cell(s) attached to a heat sink containing frustum cones by the described process.

FIG. 9 is a flow chart of a method of installing a photovoltaic tile.

FIG. 10 is a flow chart of an alternative method of installing a photovoltaic tile.

### DETAILED DESCRIPTION

The following description is presented to enable a person of ordinary skill in the art to make and use the invention. Descriptions of specific materials, techniques, and applications are provided only as examples. Various modifications to the examples described herein will be readily apparent to those of ordinary skill in the art, and the general principles defined herein may be applied to other examples and applications without departing from the spirit and scope of the invention. Thus, the present invention is not intended to be limited to the examples described and shown, but is to be accorded the scope consistent with the appended claims.

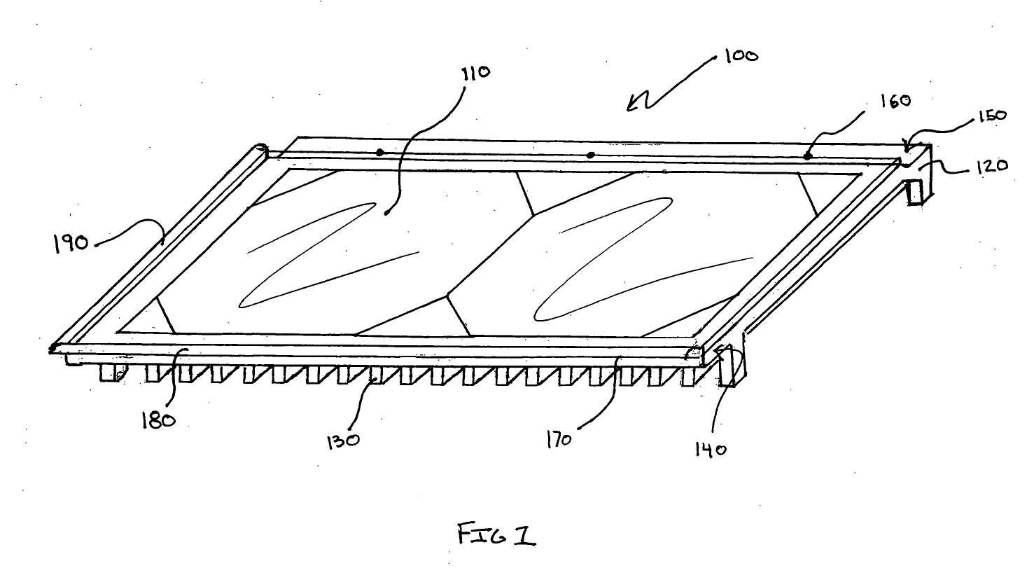

FIG. 1 illustrates an example of a photovoltaic (PV) tile 100 of the present invention. The photovoltaic tile 100 comprises one or more photovoltaic cells 110 positioned in a housing 120. The housing may lie on an unfinished roof surface horizontally with respect to the length of the roof. Each photovoltaic cell is positioned within the housing 120 to allow exposure of a light-receiving surface to solar radiation. When more than one photovoltaic cell is housed in or on the tile, each cell may be electrically connected to an adjacent cell.

Each photovoltaic cell 110 may be any currently used in the art or developed in the future, such as a silicon-based wafer photovoltaic cell, a thin film photovoltaic cell, or a conductive polymer that converts photons to electricity. Such cells are well-known and include wafer-based cells formed on a monocrystalline silicon, poly- or multicrystalline silicon, or ribbon silicon substrate. A thin-film photovoltaic cell may comprise amorphous silicon, poly-crystalline silicon, nano-crystalline silicon, micro-crystalline silicon, cadmium telluride, copper indium selenide/sulfide (CIS), copper indium gallium selenide (CIGS), an organic semiconductor, or a light absorbing dye.

Each photovoltaic cell 110 may be of any shape (e.g. square, rectangular, hexagonal, octagonal, triangular, circular, or diamond) and located in or on a surface of a tile. A photovoltaic cell in a tile is one recessed within the tile frame with essentially only the top surface of the cell exposed to the light source. A photovoltaic cell on a tile is one placed directly on top of the frame with essentially only the bottom surface not exposed to the light source.

Photovoltaic Tiles with Heat Sink

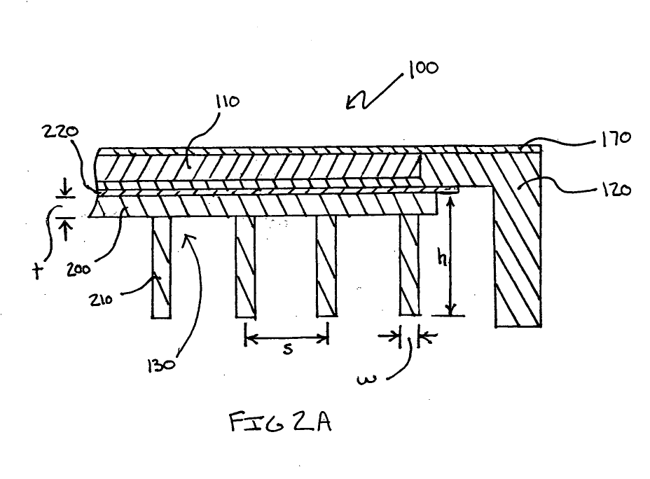

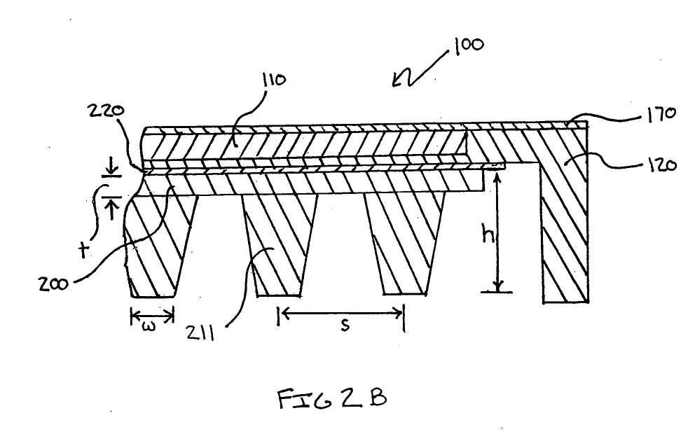

The photovoltaic tile may optionally comprise one or more heat sinks 130 in thermal communication with the unexposed surface of the photovoltaic cells 110 to dissipate the waste heat from the cells. FIG. 2A shows a detailed partial view of an attached heat sink wherein the heat sink has fins. Each heat sink may comprise a base 200 attached to the flat surface of the unexposed surface of the solar cells and a plurality of fins 210 extending substantially perpendicular to a large surface of the base. Each fin may project from the base parallel to an adjacent fin. The base and fins may be constructed separately and later joined, or constructed as one unit from the same material source. FIG. 2B shows a similar detailed partial view of an attached heat sink wherein the heat sink has frustum cones. Each heat sink may comprise a base 200 attached to the flat surface of the unexposed surface of the solar cells and a plurality of frustum cones 211 extending substantially perpendicular to a large surface of the base.

The heat sink may be in direct physical contact with the solar cells or may have one or more intervening layers. An example of an intervening layer is an intervening thermal interface layer 220, which can be made of any material used in the art, such as thermally conductive grease or adhesive (e.g. conductive epoxy, silicone, or ceramic) or an intervening conductive polymer (such as a thermally conductive polymer available from Cool Polymers, Inc., nylon 6-6, and/or a polyphenylene sulfide, optional mixed with one or more metallic fillers). The thermal interface layer may be of any material commonly used in the art (e.g. ethyl-vinyl-acetate (EVA), polyester, Tedlar®, EPT). The thermal interface layer may be constructed of material that is both electrically isolative and thermally conductive. The thermal interface layer may be a thin layer of polymer that is not intrinsically thermally conductive but, due to its thinness, conducts heat at a sufficient rate that it is considered thermally conductive. Other layers may be present separately or in addition to an intervening thermal interface layer, such as one or more electrically insulating layers. The intervening layer may be in simultaneous contact with both the solar cell(s) and the heat sink.

The base 200 and fins 210 (or cones 211) of each heat sink can be independently constructed of one or more thermally conductive materials, such as aluminum or aluminum alloy (e.g. 6063 aluminum alloy, 6061 aluminum alloy, and 6005 aluminum alloy), copper, graphite, or conductive polymer (such as conductive elastomer as available from, e.g. Cool Polymers, Inc.), and may be of any color, such as blue, black, gray, or brown. Dark colors may improve heat sink performance. A heat sink constructed of metal may be anodized or plated. Heat sinks may be constructed by common manufacturing techniques such as extrusion, casting, or injection molding, or may be constructed using a combination of manufacturing techniques to construct hybrid heat sinks (e.g. aluminum fins molded into a conductive polymer base).

In some instances, the efficiency of the heat sink in lowering the temperature of the photovoltaic cell(s) may depend on the thermal conductivity properties of the heat sink and the amount of contact made between the surface of the heat sink and the photovoltaic cell(s). In other instances, the efficiency of the heat sink in lowering the temperature of the photovoltaic cell(s) may depend on the surface geometry of the heat sink and the amount of convection.

FIGS. 2A and 2B illustrate dimensions of a heat sink 130 attached to a photovoltaic tile. The base 200 has a thickness designated as t. The fins 210 or frustum cones 211 independently have a height designated h, a center to center spacing designated as s, and a width (in the case of fins) or inner diameter (in the case of frustum cones) designated as w. The width w of any fin may be independently less than 1 inch, or less than 0.75″, or less than 0.5″, or less than 0.3″, or less than 0.2″, or less than 0.15″, or less than 0.1″, or less than 0.05″, or less than 0.025″, or less than 0.01″, or less than 0.005″, or less than 0.0025″, or less than 0.001″, or between 0.001″ and 0.25″, or between 0.002″ and 0.1″, or between 0.005″ and 0.075″, or between 0.01″ and 0.06″, or between 0.02″ and 0.05″, or 0.02″. The height h of any fin may be independently greater than 0.1″, or greater than 0.25″, or greater than 0.5″, or greater than 0.75″, or greater than 1″, or greater than 2″, or greater than 3.5″, or between 0.25″and 7″, or between 0.5″ and 6″, or between 0.75″ and 5″, or between 0.8″ and 2.5″, or between 0.9″ and 2″, or between 0.9″ and 1.25″, or 1″. The center to center spacing s between fins may be independently between 0.05″ and 1″, or between 0.075″ and 0.9″, or between 0.1″ and 0.8″, or between 0.2″ and 0.7″, or between 0.2″ and 0.5″, or between 0.25″ and 0.45″, or between 0.25″ and 0.4″ or between 0.3″ and 0.4″, or between 0.3″ and 0.45″, or between 0.35″ and 0.4″. The thickness t of the base of each heat sink may be independently less than 1″, or less than 0.75″ or less than 0.5″, or less than 0.4″, or less than 0.3″, or less than 0.2″, or less than 0.15″, or less than 0.1″, or less than 0.05″, or between 0.05″ and 0.5″, or between 0.075″ and 0.35″, or between 0.1″ and 0.25″, or between 0.1″ and 0.2″, or 0.1″, or 0.15″, or 0.2″. The ratio of center to center spacing (s) to the fin height (h) (i.e. s/h) may be independently 0.1, 0.15, 0.2, 0.25, 0.3, 0.35, 0.4, 0.45, 0.5, 0.5, 0.6, 0.65, 0.7, or between 0.1 and 0.7, or between 0.15 and 0.5, or between 0.2 and 0.4, or between 0.2 and 0.35, or between 0.25 and 0.3. The dimensions of any fin may be identical or different from the dimensions of other fins on the same heat sink. The dimensions of any fin or base may be identical or different from the dimensions on other heat sinks. The dimensions of all heat sink bases on a tile may be the same. The dimensions of all heat sink fins of all heat sinks on a tile may be the same.

The dimensions of each heat sink may independently be any combination of the dimensions described above, such as w between 0.002″ and 0.1″, h between 0.75″ and 5″, s between 0.2″ and 0.5″, and t between 0.1″ and 0.25″; w between 0.001″ and 0.25″, h between 0.75″ and 5″, s between 0.2″ and 0.5″, and t between 0.1″ and 0.25″; w between 0.02″ and 0.05″, h between 0.75″ and 5″, s between 0.2″ and 0.5″, and t between 0.1″ and 0.25″; w between 0.002″ and 0.1″, h between 0.25″ and 7″, s between 0.2″ and 0.5″, and t between 0.1″ and 0.25″; w between 0.002″ and 0.1″, h between 0.9″ and 2″, s between 0.2″ and 0.5″, and t between 0.1″ and 0.25″; w between 0.002″ and 0.1″, h between 0.75″ and 5″, s between 0.05″ and 1″, and t between 0.1″and 0.25″; w between 0.002″ and 0.1″, h between 0.75″ and 5″, s between 0.3″ and 0.4″, and t between 0.1″ and 0.25″; w between 0.002″ and 0.1″, h between 0.75″ and 5″, s between 0.2″ and 0.5″, and t between 0.05″ and 0.5″; and w between 0.002″ and 0.1″, h between 0.75″ and 5″, s between 0.2″ and 0.5″, and t between 0.1″ and 0.2″.

A heat sink may be designed such that a first volume (defined as a volume of a heat sink including its associated heat sink base) is a percentage of a second volume (defined as a volume from a top-down projected surface area of the heat sink base and a third dimension, wherein the third dimension is defined by the least squares determination from the heights of each protrusion on the heat sink base (such as cones, fins, etc.)). For example, if all protrusions of a heat sink are of equal dimensions then the first volume would be the heat sink base volume added to the product of the volume of each protrusion and the number of protrusions; and the second volume would be the top-down projected surface area of the heat sink base (e.g. width×length, if the heat sink base were rectangular) multiplied by the protrusion height (i.e. the third dimension). If the heights of protrusions within a heat sink are different, then the least squares determination of all protrusion heights would determine the third dimension used in the example above. The percent volume is the first volume divided by the second volume×100. The percent volume may be, for example, between 10% and 50%, between 15% and 45%, between 20% and 40%, between 25% and 35%, between 20% and 30%, between 25% and 30%, between 30% and 35%, between 35% and 40%, between 40% and 45%, between 45% and 50%, between 20% and 25%, between 15% and 20%, between 10% and 15%, between 10% and 20%, between 15% and 25%, between 25% and 35%, between 30% and 40%, between 35% and 45%, between 40% and 50%, between 10% and 25%, between 15% and 30%, between 20% and 35%, between 25% and 40%, between 30% and 45%, between 35% and 50%, between 10% and 12.5%, between 12.5% and 15%, between 15% and 17.5%, between 17.5% and 20%, between 20% and 22.5%, between 22.5% and 25%, between 25% and 27.5%, between 27.5% and 30%, between 30% and 32.5%, between 32.5% and 35%, between 35% and 37.5%, between 37.5% and 40%, between 40% and 42.5%, between 42.5% and 45%, between 45% and 47.5%, or between 47.5% and 50%.

A long axis of fins 130 may be substantially parallel or substantially perpendicular to a long axis of the base, for instance. Substantially parallel is when two referenced axes form an angle of less than 10°. Substantially perpendicular is when two referenced axes form an angle between 85° and 95°. A long axis is an axis parallel to the longest straight edge of the object referenced. A long axis is implied if no axis is referenced. The fins may run continuously along most or all of the length of the base. Fins may not all form the same angle with respect to the long axis of the heat sink (e.g. a fan orientation), so that air may pass freely through many of the channels formed by adjacent fins regardless of wind direction. Surfaces of fins may also have features such as ridges or bumps that help induce eddies in air flowing past the fins to help convection.

One or more heat sinks may, for instance, be positioned substantially parallel or substantially perpendicular to the long axis of the tile 100 and may span portions of or the entire length or width of the tile. Likewise, multiple heat sinks may be aligned in tandem, with or without intervening space, to span the portions of or the entire length or width of the tile, if desired. In one variation a heat sink has sufficient length to span greater than ¾ of the length of the tile. In another variation a heat sink has sufficient length to span greater than ¾ of the width of the tile. In some variations different heat sinks on the tile will be positioned substantially perpendicular to one another. In another variation a single heat sink is oriented to cover most of the unexposed surface of the photovoltaic cell(s). The heat sink may also be located on the sides and/or top of the tile to increase convection and cooling efficiency.

A heat sink may be of various designs to provide increased heat transfer. For example, fins may contain breaks in their length, such as to create channels across fins (or equivalent), to provide additional openings to the interior of the heat sink and increased airflow to the internal fins. Channels may be of any pattern, such as general cross-cut, herringbone, or undulating. The fins may also be replaced with other heat dissipating shapes attached to the base, such as pyramids (including frustum pyramids), cylinders, square pegs, or cones (including frustum cones). Other shapes (such as frustum cones) may be aligned in parallel rows and columns across the length and width of the heat sink, respectively; or in staggered parallel rows and columns across the length and width of the heat sink, respectively. The use of frustum cones may allow wind current from any direction to contribute to the convection of the heat sink and increase cooling of the photovoltaic tile.

The heat sink may be configured to reduce temperature of a photovoltaic cell in ambient quiescent air that is at standard temperature and pressure and an irradiance (E) by white light individually or in any combination of 800 W*m⁻², 1000 W*m⁻², or 1200 W*m⁻² by at least 1° C.; or by at least 2° C.; or by at least 5° C.; or by at least 7° C.; or by at least 10° C.; or by at least 12° C.; or by at least 15° C.; or by at least 20° C. as compared to an identical cell lacking the heat sink. The size, number, and spacing of fins, the size of the base portion, and the materials of construction of the heat sink may be selected based on the desired decrease in temperature over the comparative PV cell.

The heat sink may be configured to maintain the photovoltaic cell at a temperature below about 175° F., or below about 160° F., or below about 150° F., or below about 140° F., or below about 13020 F., or below about 120° F., or below about 110° F., or below about 100° F., or below about 90° F., or below about 80° F. in ambient air at a temperature of 70° F.

The heat sink may be configured to increase the energy conversion efficiency (defined by the equation: η=(Pₘ/(E×A_{c})), where Pₘ is maximum electrical power in watts, E is the input light irradiance in W*m⁻² and Ac is the surface area of the solar cell in m²) or total-area efficiency of a photovoltaic cell (which may be defined by the relative change in current (I) and/or voltage (V) or relative change in the product of I and V) in ambient quiescent air that is at standard temperature and pressure and an irradiance (E) by white light individually or in any combination of 800 W*m⁻², 1000 W*m⁻², or 1200 W*m⁻² by at least 0.5%; or by at least 1%; or by at least 1.5%; or by at least 2%; or by at least 2.5%; or by at least 3%; or by at least 3.5%; or by at least 4%; or by at least 4.5%; or by at least 5%; or by at least 5.5%; or by at least 6%; or by at least 6.5%; or by at least 7%; or by at least 7.5%; or by at least 8%; or by at least 8.5%; or by at least 9%; or by at least 9.5%; or by at least 10% as compared to an identical cell lacking the heat sink.

If desired, the heat sink may be subjected to forced airflow provided by any means, e.g. one or more fans, to increase airflow over the heat sink and increase cooling effectiveness of the photovoltaic cell. A fan may deliver the forced air to the heat sink by direct exposure or remotely through a duct system.

A photovoltaic tile may comprise a flange or lip (straight or curved) on a housing oriented to direct air flowing through the heat sink underneath a tile upward upon exiting the tile. This feature may prevent hot air generated from a heat sink from entering an adjacent tile. Likewise, a flange or lip may be oriented to force fresh cold air flowing above a tile or adjacent tile into a heat sink. A feature of this orientation may be particularly useful to prevent trapping a layer of warm air underneath an array of tiles and permit cool air to enter the underside to promote efficient heat transfer. Multiple flanges and/or lips may be incorporated into a single tile to direct cool air into a heat sink and to direct hot air away from a heat sink.

The tiles may be configured to provide air-flow channels that allow air to circulate via natural convection or forced convection caused by wind past heat sinks to cool photovoltaic cells. Air-flow channels of individual tiles may be aligned with air flow channels of one or more adjacent tiles to provide continuous air flow through the heat sinks of multiple tiles. The channels may be oriented such that air may flow parallel or perpendicular to the roof line through the heat sinks of individual tiles or continuously through the heat sinks of multiple tiles. Ducts or plenums (not shown for sake of clarity) may be provided along the edges of tile arrays.

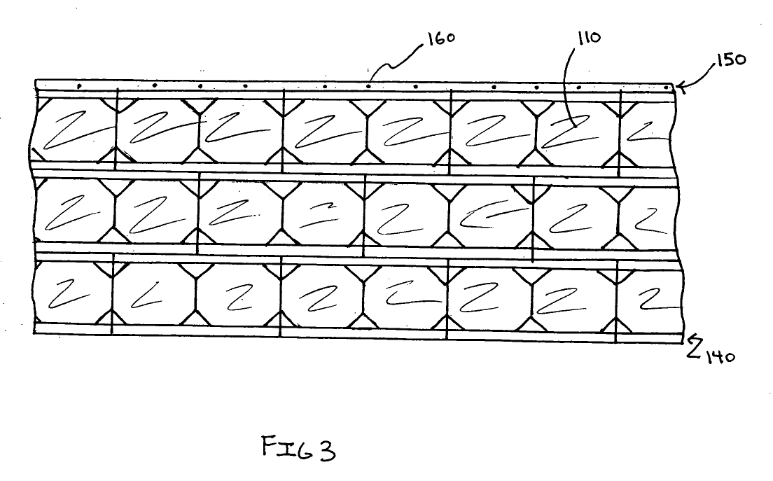

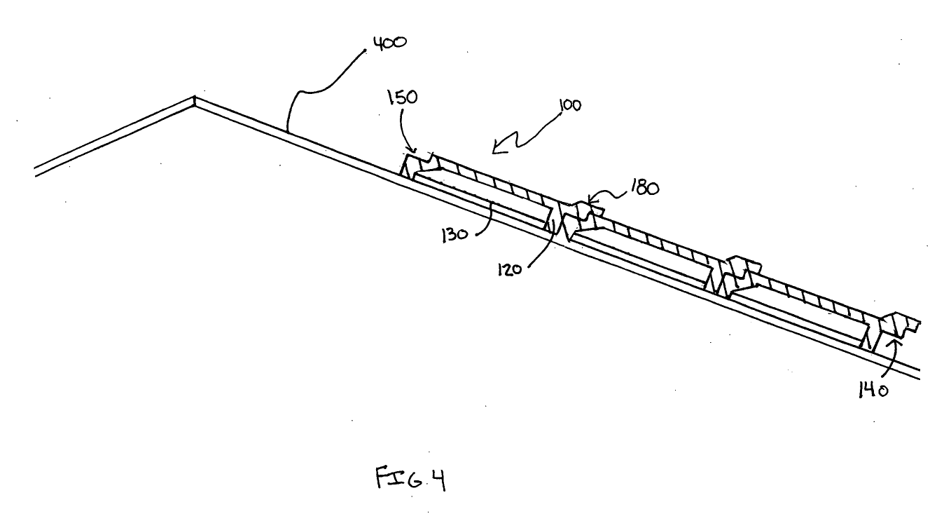

Tiles may be designed to partially overlay one another such that a collection of tiles protects an unfinished rooftop from weather exposure. To aid in weather protection, tiles may have one or more projections (such as 140 in FIG. 1) which complement one or more depressions (such as 150 in FIG. 1) in an adjacent tile. The tiles may be arranged such that a projection 140 when located on the lower end of a tile overlaps a depression 150 located on the upper end of an adjacent tile as shown in FIGS. 3 and 4. When placed on a sloped rooftop 400 the projections may prevent rainfall from reaching the underlying roof (FIG. 4) and/or add structural integrity to the tile array. The tiles may have one or more overhangs (such as 180 and 190 in FIGS. 1 and 4) which do not have corresponding depressions in adjacent tiles. These features add additional weather protection since no vertical seams are exposed to the outside surface when adjacent tiles are joined. The arrangement of overhangs and depressions may be of any combination and used e.g. on the sides of a tile, individually or in addition to the upper and lower ends, to prevent exposure of electrical connections, fasteners, and the roof surface. A sealant may be used at seams between joined tiles (e.g. those underneath a projection/overhang) to provide additional weather protection.

Mounting holes (160 in FIG. 1) may be included in the base to fasten the tiles to a rooftop (400 of FIG. 4) before placement of an overlapping adjacent tile. These holes are preferably located along or near the edge opposite the photovoltaic cell such that the adjacent row of tiles may overlap the mounting holes when installed on a roof to prevent exposing fasteners to weather. The tiles may additionally or alternatively have tabs with holes attached to the base along the edge near holes 160 so that e.g. nails or screws may be inserted into them to affix the tile to portions of a roof structure such as framing and wood panels that lie under the tiles.

The electrical configurations between individual photovoltaic cells 110 as well as the electrical connections between individual tiles may be independently configured as series, parallel, or mixed series-parallel as is well known in the art to achieve the desired operating current and voltage. For example, individual photovoltaic cells within a tile may be connected in series to increase the total operating voltage of the tile. If the voltage produced by each individual photovoltaic cell within a tile is sufficient, then the cells may be connected to adjacent cells in parallel to maintain voltage, increase current, and/or so that failure of one cell does not inactivate all cells of the tile.

The tile may contain a protective layer 170 (as shown in FIG. 1) adjacent to the light-receiving surface of each photovoltaic cell to protect the photovoltaic cells from damage (caused, for example, from moisture, dust, chemicals, and temperatures changes), while allowing the transmission of sunlight. The protective layer may conform to the surface shape of the photovoltaic cells and may be made of any suitable material, such as glass (e.g. low-lead tempered glass) or polymer (e.g. polymerized para-xylene, vapor phase deposited para-xylene, or ethylene vinyl-acetate). The protective layer may be a film (clear or colored) and be made of e.g. acrylics, epoxies, urethanes, and silicones. The protective layer may optionally be an antireflective coating, such as silicon nitride.

A photovoltaic tile may be formed in standard lengths of approximately e.g. 6 inches, 12 inches, 18 inches, 24 inches, 30 inches, 36 inches, 42 inches, or 48 inches, with any combination of standard widths of approximately e.g. 4 inches, 8 inches, 12 inches, 18 inches, 22 inches, 26 inches, 30 inches, or 38 inches.

Photovoltaic tiles typically contain 1, 2, 3, 4, 5, 6, 7, 8, 9, 10, 11, 12, 15, 18, 21, 24, 27, 30, 20, 24, 28, 32, 36, 40, 25, 36, 45, 50, 42, 48, 54, 60, or 72 PV cells arranged in rows and columns. PV cells may be arranged, for instance, 1×2, 1×3, 1, ×4, 2×2, 2×3, 2×4, 2×6, 2×8, 3×3, 3×4, 3×5, 3×6, 3×7, 3×8, 3×9, 3×10, 4×4, 4×5, 4×6, 4×7, 4×8, 4×9, 4×10, 5×5, 5×6, 5×7, 5×8, 5×9, 5×10, 5×12, 6×6, 6×8, 6×10, 6×12, or 8×12. A tile may, for example, have one, two, three, four, five, six, seven, eight, nine, or ten or more heat sinks in instances where a single heat sink is in contact with cells across an entire row of PV cells or in the tile.

Polymers may be used to allow increased design flexibility in making the tile and/or heat sink. In one variation, a photovoltaic tile may comprise photovoltaic cell(s) within an integrated thermally conductive polymeric housing such that the housing itself acts as a heat sink. The polymer may be a thermally conductive polymeric material (e.g. CoolPoly® thermally conductive plastics, nylon 6-6, and/or a polyphenylene sulfide, optional mixed with one or more metallic fillers) so that the entire housing may support the photovoltaic cell(s) (and any integrated components) while also transferring heat away from the photovoltaic cells. This arrangement may decrease the number of components and interfaces between the photovoltaic cell(s) and increase the overall surface area of the heat sink. The housing may be comprised of multiple types of polymers (e.g. 2 or 3) to form different components of the tile where each component may have different polymeric properties. For example, one polymer may be a thermally conductive polymer attached to a photovoltaic cell and acting as a heat sink, while another polymer may surround the photovoltaic cell and/or photovoltaic cell/heat sink interface to provide e.g. structural integrity, aesthetic appeal, weather resistance, and/or a roof-mounting surface. In another variation, one or more polymers may be used to form the tile housing (and/or a portion of the heat sink), while metal may be used to form the heat sink (or a portion of the heat sink).

Interlocking Photovoltaic Tiles

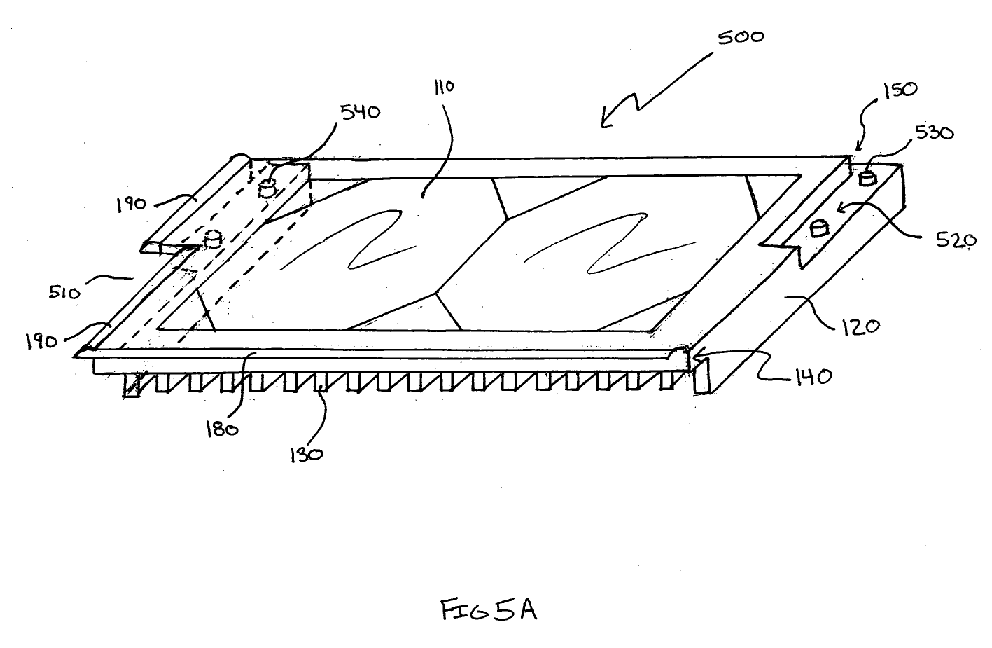

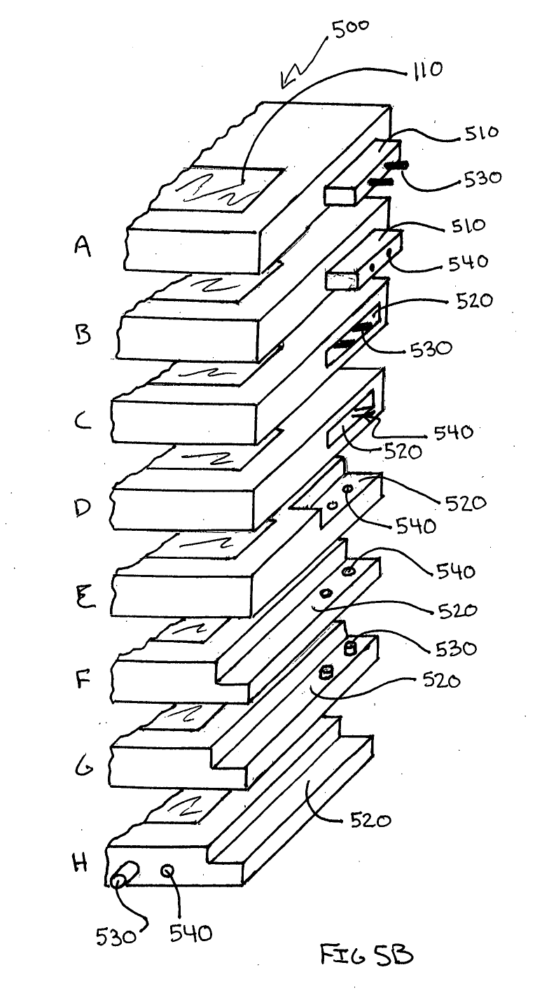

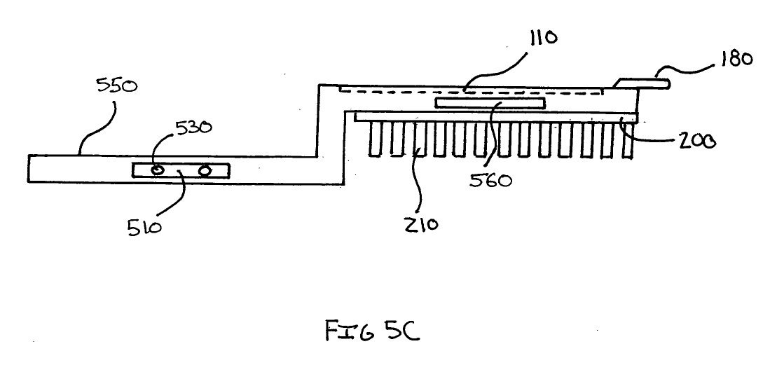

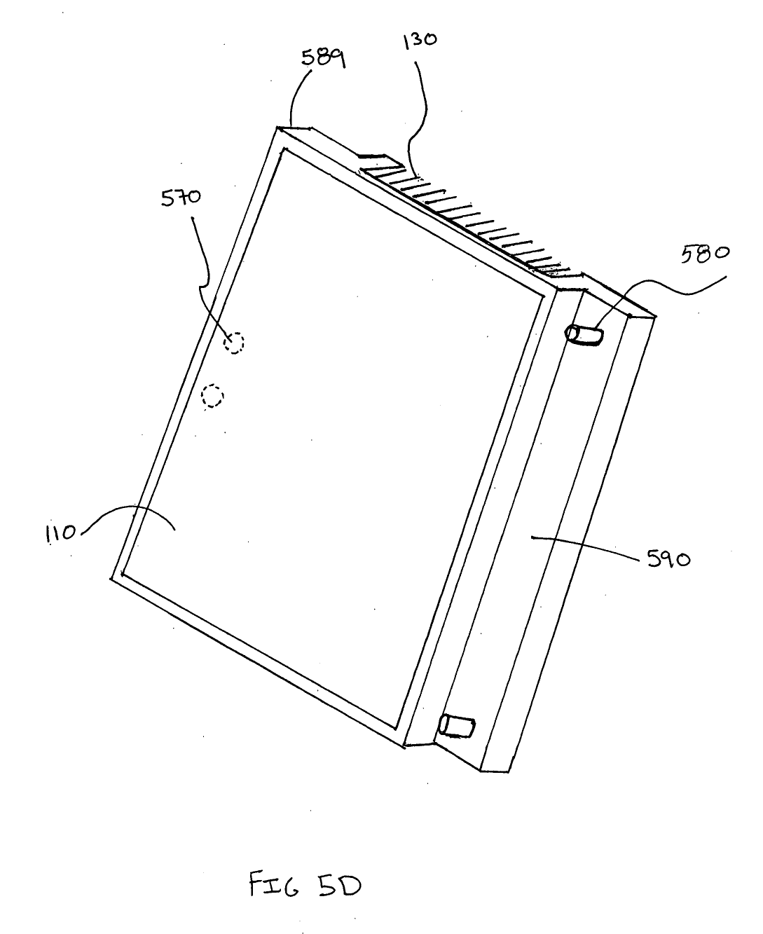

FIG. 5A illustrates a photovoltaic roofing tile as also comprising a rigid interconnect system. As with other photovoltaic tiles described, the interlocking photovoltaic tile 500 comprises a housing 120 and one or more photovoltaic cells 110 disposed in or on the tile to allow exposure to direct solar radiation from the top surface of the tile. The tile may also comprise a heat sink 130 in any variation described herein. Both the left and right sides of the tile may comprise either a male base connector 510 or a female base connector 520 configured as part of the tile housing. A base connector of each tile is designed to partially overlap a base connector of an adjacent tile. The male base connector may be of any design such that material generally extends outside of the housing 120 (e.g. a tab or shelf), while the female base connector may be any design such that material is generally removed from the housing 120 (e.g. a rabbet or mitered edge). The base connectors may be of any shape or orientation (e.g. occupy the entire length of one side of a tile, or occupy only a portion of one side of a tile) to complement the base connector of an adjacent tile.

Upon each base connector may be one or more electrical projections 530 and/or electrical sockets 540, where an electrical projection and an electrical socket are designed to complement one another and permit continuity of current. Thus, each electrical connector may comprise a base component and an integrated electrical component in one of at least four combinations: (1) a male base connector 510 containing an electrical projection 530, (2) a male base connector 510 containing an electrical socket 540, (3) a female base connector 520 containing an electrical projection 530, and (4) a female base connector 520 containing an electrical socket 540.

The interlocking tiles are designed such that a connector on one tile is designed to complement an adjacent tile connector to form a substantially rigid connection between adjacent tiles while maintaining continuity of electrical current, thus limiting the complexity of installation and reducing installation costs. Once two tiles are connected by the connector, the tiles are essentially movable as a unit. There may be little to no relative movement between tiles when they are individually twisted about an axis of the tiles.

The electrical sockets and projections may be oriented in any direction (e.g. perpendicular or parallel) to the orientation of a base connector and may be of any combination (such as a mixture of projections and sockets) to complement an adjacent tile. The electrical sockets and projections may be arranged asymmetrically and opposite relative the position of the photovoltaic cell(s) such that when one row of tiles overlaps an adjacent row of tiles each electrical connection is disposed directly underneath a row of overlapping tiles to prevent exposure to weather.

A plug and socket connection or a hermaphroditic electrical connection may be used in lieu of a projection and socket electrical connection. Projections or plugs include any connector extending out from its surface, including mechanical springs, pins or prongs. The electrical connections are not limited to the projection-socket arrangement and may include any device that allows continuity of electrical current while maintaining a substantially rigid mechanical connection. For example, an electrical connection may comprise two electrodes disposed as a film on the surface of two complementary and interlocking adjacent tiles. Pins used as electrical connectors may having springs that help lock the pins into receptacles, providing a stronger connection between tiles.

Some roof tiles are designed to be laid on a roof such that the longitudinal or major axis of each tile is parallel to the roofline to provide overlapping rows of tiles that parallel the roof-line. Rectangularly-shaped roof tiles are commonly installed in this manner. Connectors on this or other roof tiles as described herein may be positioned at the ends of a major or longitudinal axis of a roof-tile so that adjacent tiles may be interconnected along a row parallel to the roofline. An alternative to this configuration is for the connectors to be positioned at the ends of a minor or latitudinal axis of the roof-tile so that adjacent tiles may be interconnected generally in columns toward the roofline so that adjacent tiles are interconnected in a direction toward or away from the roofline. The connectors may be positioned in a combination of longitudinal and latitudinal axis.

FIG. 5B illustrates various electrical/mechanical configurations for one side of a tile that may be used with the present invention. Each tile may have a complementary electrical/mechanical connector on the opposite side of the tile (not shown). Tile A shows a male base connector 510 with electrical projections 530. This configuration is designed to match a complementary adjacent tile having a female base connector 520 and an electrical socket 540 (such as the mirror image of the connector shown in tile D). The connector in tile A in the variation shown is placed along an edge such that when two identical tiles are laid parallel with respect to the roof line the electrical insertion is horizontal (or parallel) with respect to the roof surface and parallel with respect to the roof line. Tile B shows a similar connector configuration to tile A, but the electrical projections have been replaced with electrical sockets. Tile E shows a similar connector configuration to that shown in FIG. 5A wherein the sockets and projections have been replaced with projections and sockets, respectively. The tile in FIG. 5A and tiles E-G of FIG. 5B are examples wherein insertion of the connectors is made perpendicular with respect to the roof surface. Tiles F and G of FIG. 5B show similar socket configurations to the tile of FIG. 5A where the female base connector extends through the entire edge of the tile. Other connector variations are within the scope of the present invention. For example, connectors may be mixed socket/projection (as shown in tile H) and/or on a surface perpendicular to the roof line (also shown in tile H) or on more than one surface of the tile (such as a long edge and a short edge).

FIG. 5C illustrates a side view of an additional aspect of the invention. The tile may be shaped to allow substantial overlap of an adjacent tile when installed. The overlap also helps protect the electrical and mechanical connector. Heat sink fins of one tile 210 may touch the fin-receiving surface 550 of an adjacent tile and can be adhered to the surface using e.g. epoxy cement or bitumen. The overhang 180 may overlay an adjacent tile and can be adhered or waterproofed to prevent water from getting between tiles. An additional mechanical connector 560 may be provided in this instance to provide extra strength to the installation and help guard against wind-lift of tiles that can occur during severe storms.

FIG. 5D depicts a rectangular roof tile having a solar cell 110 (or multiple solar cells, e.g. 3-5) in which the tile will be installed with its longitudinal axis parallel to the roofline. Connectors may be on opposite long sides of the tile (e.g. 580 as shown in figure SD) or on the central portion of the joint (e.g. 570) to permit tiles to be connected to adjacent tiles in a direction that is generally perpendicular to or intersects at an angle the roof-line on which the tile will be installed. Sections of tiles can therefore be laid by placing one tile with projection 589 in the vicinity of the roof-line and then inserting two tiles (in this instance) in the adjacent row next furthest from the roof-line, then repeating the procedure until the photovoltaic tiles extend close to the edge of the roof closest to ground level toward the roof-line. Assembling the roof in thin vertical sections in this manner leaves a major surface of the roof accessible to ease further tile installation. Upon installation, the projection 589 overlaps a portion of an adjacent tile (at 590). Projections similar to 589 may be formed on one or more sides of each tile such that all sides of each tile are either overlapping or being overlapped by an adjacent tile.

The tile in figure SD additionally comprise a metal frame (e.g. aluminum) and may be used in combination with any heat sink design (such as an aluminum heat sink of folded sheet metal fins 0.01″-0.02″ in thickness and 1″-2″ in height). The tile may also contain a protective surface or coating (e.g. glass) and mounting holes to secure the tile to the roof-top (or on top of an existing roof).

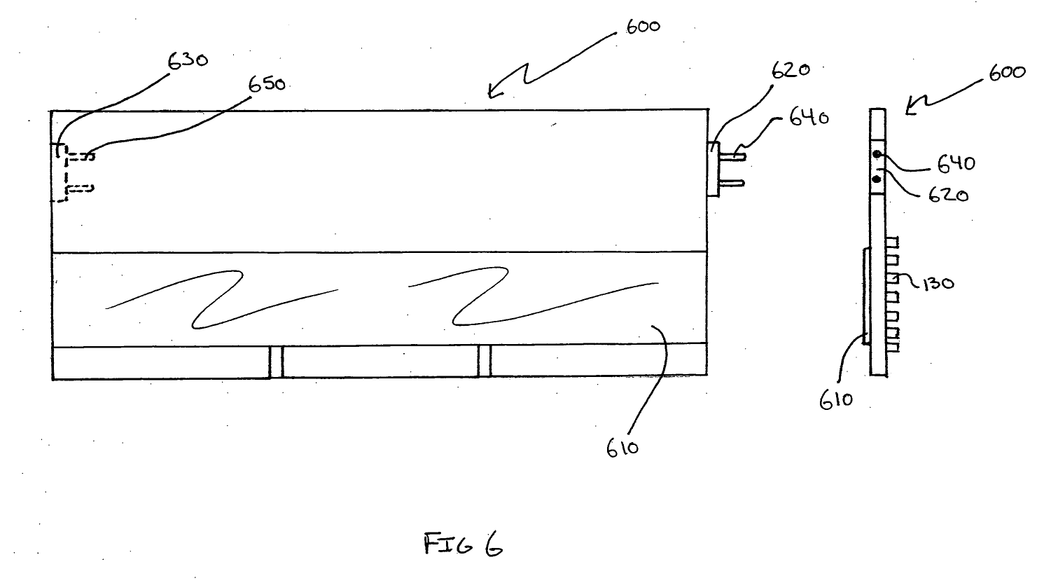

Thin film photovoltaic cells may be utilized in any aspect of the described invention. FIG. 6 illustrates a composite roofing shingle 600 with a thin film solar cell 610 applied on the upper surface of a composite shingle. A male base connector 620 and a female base connector 630 having e.g. pins 640 and corresponding receptacles 650 are provided at each end of the shingle to interface with complimentary connectors on adjacent shingles. When two or more composite shingles are connected to one another via corresponding connectors, their relative locations are established to one another such that one may not be rotated to a different direction from the other relative to a rooftop. The two shingles may be installed parallel to one another or along the same line in this instance. The rigidity of connections between tiles that removes degrees of freedom of movement of one tile relative to its adjacent tile helps assure installation in parallel rows and therefore helps ease installation. FIG. 6 also shows an optionally present heat sink 130.

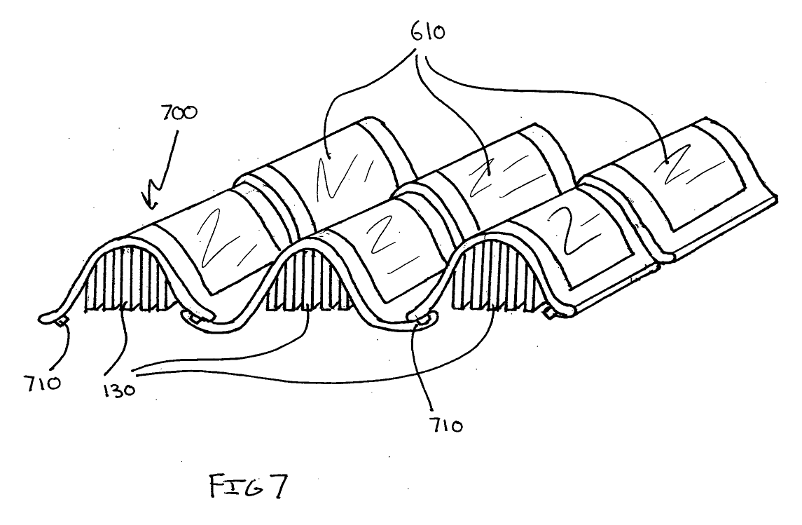

A thin film solar cell may be positioned on e.g. ceramic or concrete tiles as well. FIG. 7 illustrates ceramic shaped tiles 700 that have photovoltaic cells (PV) or thin-films 610 in or on surfaces of tiles. The thin-film may be adhered to a copper sheet, which is then adhered to the tile or may be printed directly onto the module. The thin-film may be of any material, size, or configuration and may be any color or combination of colors. The tile bases may be made of any material e.g. ceramic, cement, metal, composite, or polymer, and act as a frame to house additional components of the tile. The tiles may have a heat sink 130 that is embedded in and contacts the respective cells. Interlocking connectors 710 may provide the mechanical and electrical connections that lock tiles in place as well as conduct electricity from one tile to the next. The curved configurations of the tiles provide large surface areas for their respective cells to occupy, increasing electrical output for a given square footage, of roof-top, and the curved configurations also provide large fluid-conducting channels into which fins of heat sinks may extend. Air or other cooling medium may therefore pass with less resistance and aid in cooling the photovoltaic cells more effectively. Channels may be used in this or any other tile configuration herein so that liquid coolant may be pumped through the channels to decrease the photovoltaic cell operating temperature.

Method of Fabrication

A tile may be formed a number of ways. For instance, a tile may be formed of a polymer or composite mix in a mold. Housing portions of male and female polymeric connectors are placed in the mold, as are e.g. tubes to carry wiring from the connectors to the photovoltaic cell or wiring itself or to a printed circuit board (PCB) with conductive lines to conduct electricity. If wires or a PCB are placed in the mold, electrical connections are made to the connector portions of the connectors. Next, the polymer or composite mixture is poured into the mold and cured to form a solid tile. The mold may be shaped to provide openings in the cured product top and bottom so that a solar cell can be inserted in the top hole and wired or soldered via e.g. solder-balls to connections on the PCB or to wires in the tile. The heat sink and/or bottom of the solar cell may then be coated with thermally conductive adhesive, the heat sink inserted into the bottom hole and into thermal contact with the solar cell, and the adhesive cured to complete the tile. Alternatively, the heat sink may be fixed to the photovoltaic cell using a lamination procedure described herein.

A tile formed of terra cotta may be likewise formed in a mold. Ceramic housings for male and female connectors are placed in the mold, as are metal tubes as conduits for wiring from the connectors to the photovoltaic cell. A clay mixture as is typically used in forming tiles is placed in the mold and fired to form the tile. The tile may have an opening from top to bottom and interfacing with the tubes. The photovoltaic cell edges are covered with a weatherproof adhesive such as silicone as are inner walls of the opening, and the cell having an anti-reflective coating is inserted into the top of the tile such that bottom edges of the cell engage a shelf formed in the tile by the mold. Excess adhesive is removed from the surface of the tile and anti-reflection coating, and the tile is set aside to give the adhesive time to set.

Wires are inserted through the tubes and out ends of the ceramic connector housings. The wires are connected to an electrical pin or receptacle assembly, and each assembly is then inserted into the corresponding ceramic connector housing with which the electrical pin assembly engages to be locked into place and form the completed connector. Wires are connected to the cell and wires running to the second connector of the tile to provide the desired electrical connection (series, parallel, or series-parallel). Once all wire connections have been made and the electrical pin assemblies seated in their respective ceramic connectors, a heat sink is coated with a thermally conductive adhesive such as thermally conductive epoxy or silicone and inserted through the hole in the bottom of the tile so that the adhesive and heat sink engage the exposed bottom of the photovoltaic cell. Once the adhesive cures, the tile comprising a roof tile, photovoltaic cell, and heat sink is ready for installation as a roof tile on a roof.

Method of Attaching Heat Sink

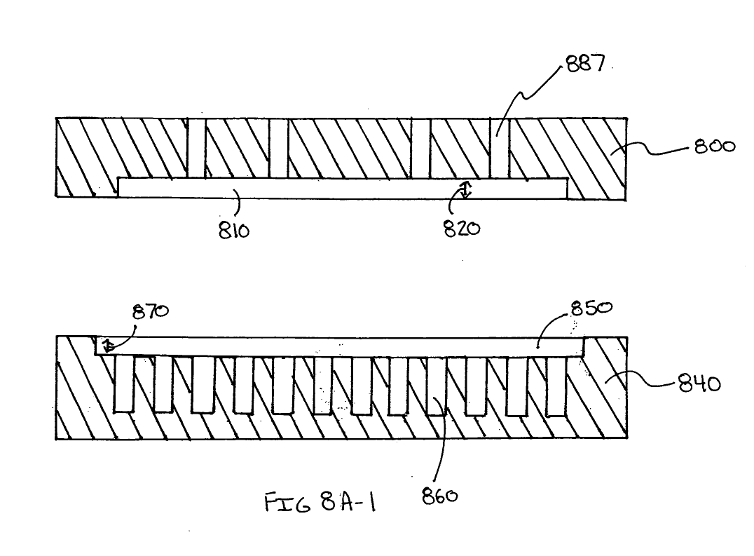

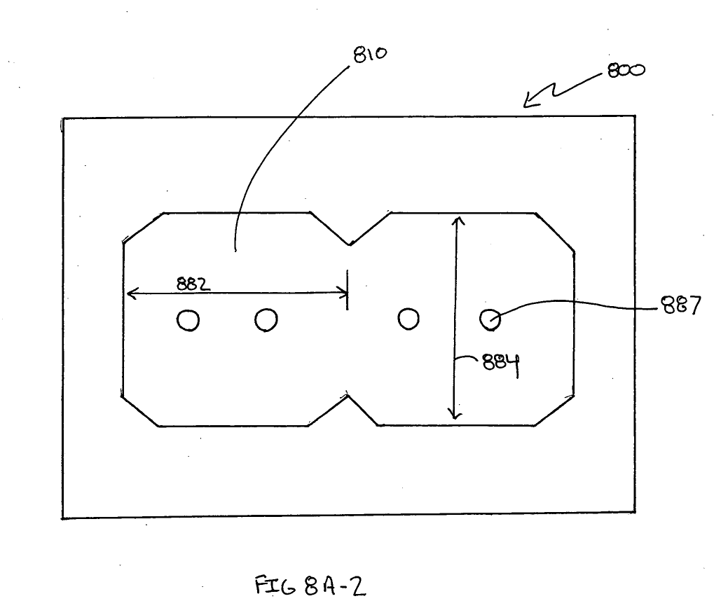

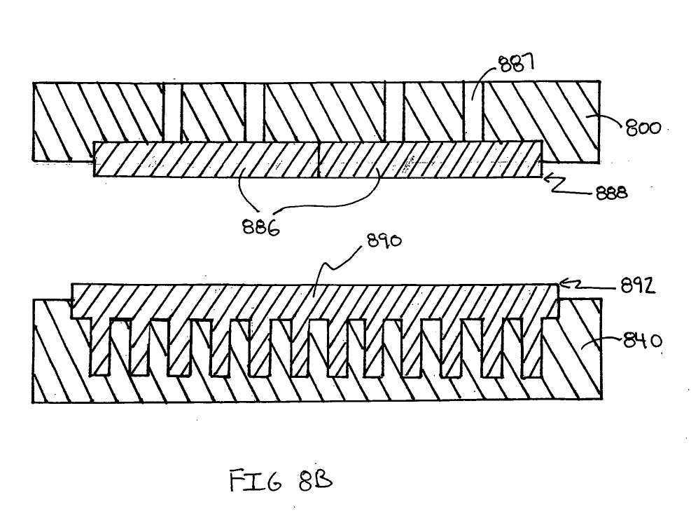

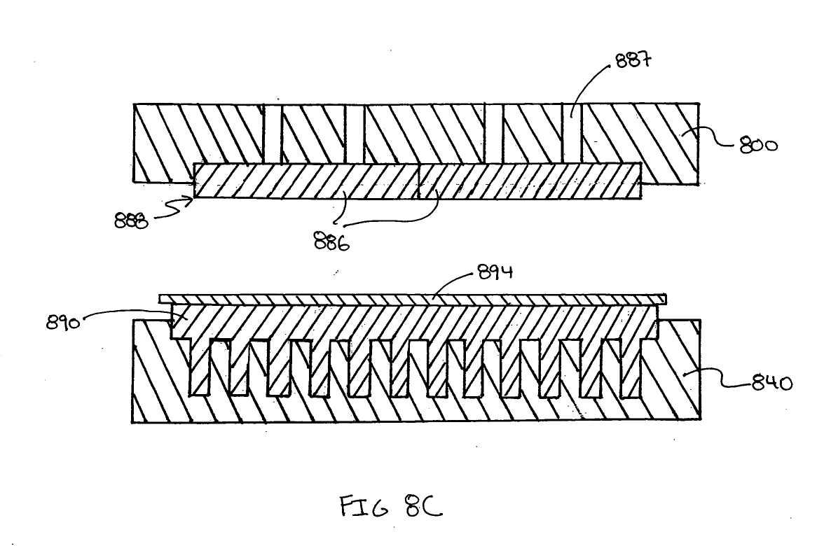

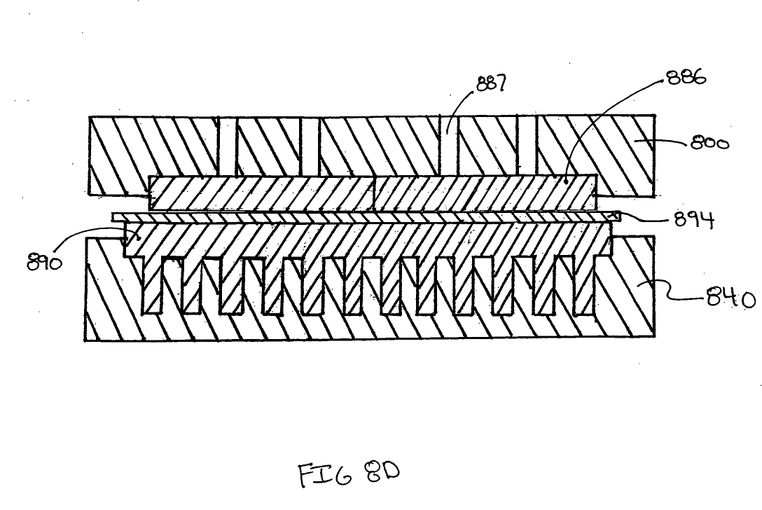

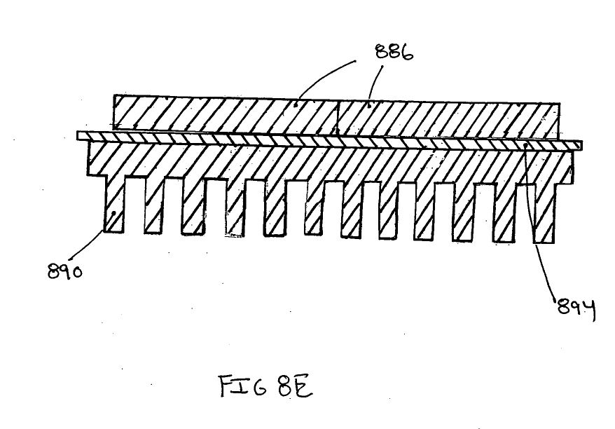

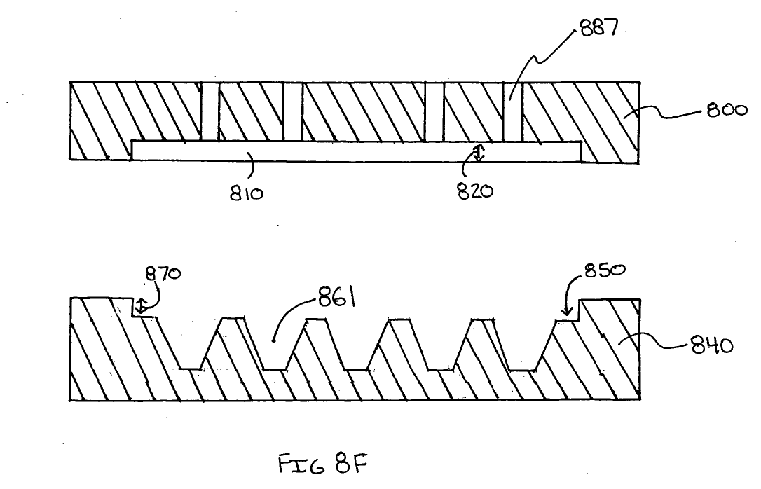

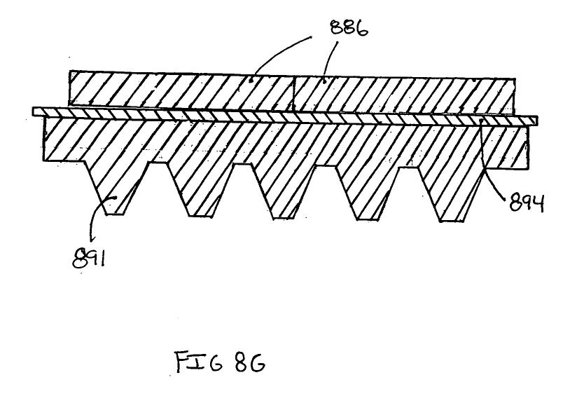

Another feature of the present invention is a method of attaching a heat sink to a photovoltaic tile. FIGS. 8A-8E are different views during the described fabrication process of a photovoltaic tile.

FIG. 8A-1 illustrates a cross-sectional view of a system used to construct a photovoltaic tile. An upper jig 800 comprises an optionally present depression 810 designed to complement one or more photovoltaic cells. The depression may have a depth 820 roughly the thickness of the photovoltaic cell(s), or less than the thickness of the cell or cells. Vacuum channels 887 in any shape, number, and configuration may be present to allow a vacuum source through the upper jig to the photovoltaic cell(s). A vacuum source may allow the photovoltaic cells(s) to be temporarily held within the depression 810 during the manufacturing process. FIG. 8A-2 shows the upper jig 800 from a bottom view. Each depression 810 is shown with its corresponding width 882 and length 884. The width and length can collectively or independently have roughly the same dimensions as the largest surface of the cell or cells, or have slightly larger dimensions. The number of depressions 810 may be united or separated and any number desired for the tile, such as 1, 2, 3, 4, 5, 6, 7, 8, 9, 10, 11, 12, 13, 14, 15, 16, 17, 18, 19, 20, or 25. The shape of a depression may be of any shape of photovoltaic cell or cells, such as square, rectangular, hexagonal, octagonal, triangular, circular, or diamond.

A lower jig 840 shown in FIG. 8A-1 may comprise a base depression 850 and a number of fin depressions 860. The base depression 850 and fin depressions 860 may be designed to collectively compliment a heat sink such that the heat sink may be inserted into the lower jig and is incapable of substantial horizontal movement following insertion. The base depression may have a depth 870 roughly the thickness of a heat sink base or slightly less than the thickness of a heat sink base, and a width roughly the same as the heat sink base or slightly larger than the heat sink base. The base depression may be optionally present. Each fin depression 860 may have roughly the same dimensions as the heat sink fins or slightly larger dimensions to allow uninhibited insertion of the heat sink. The lower jig 840 may also be designed to complement any number of heat sink designs describe herein, such as pyramids (including frustum pyramids), cylinders, square pegs, or cones (including frustum cones). Vacuum channels (not shown) may be present to provide a vacuum source through the lower jig to the heat sink, as described for the upper jig.

The material of the upper and lower jig may be independently any material known in the art, such as aluminum, copper, ceramic, and polymer. The upper jig and the lower jig may be in reverse orientation, such that the upper jig is below the lower jig.

The photovoltaic tile manufacturing process may begin by placing the photovoltaic cell(s) and the heat sink into their respective jigs, as illustrated in FIG. 8B. The upper jig 800 houses one or more photovoltaic cells 886 inserted into each depression 810 such that a flat surface of each cell 888 is exposed while most of the remaining surface area of each cell is housed within depression. Each cell may be made of any material described herein or known in the art, such as wafer-based cells formed on a monocrystalline silicon, poly- or multicrystalline silicon, or ribbon silicon substrate, and may be of any shape, such as square, rectangular, hexagonal, octagonal, triangular, circular, or diamond. The cell(s) may be temporarily fixed to the upper jig 800 by gravity, vacuum (using e.g. optionally present vacuum channels 887), or any common adherent. The lower jig 840 houses the heat sink 890 such that a flat surface of the heat sink 892 is exposed while most of the remaining surface area, such as the fins, is housed within depression. The heat sink may be made of any thermally conductive material known in the art and/or described herein, such as aluminum or aluminum alloy (e.g. 6063 aluminum alloy, 6061 aluminum alloy, and 6005 aluminum alloy), copper, graphite, or conductive polymer (such as conductive elastomer), may be of any color (e.g. blue, black, gray, or brown) and may comprise cooling surfaces configured of any geometry, such as pyramids (including frustum pyramids), cylinders, square pegs, or cones (including frustum cones). The heat sink may be temporarily fixed to the lower jig 840 by gravity, vacuum, or any common adherent.

FIG. 8C illustrates how an intervening layer 894 may be added to the exposed surface of the heat sink 892 or to the exposed surface(s) of the cell(s). The intervening layer may be a thermal interface layer, such as thermally conductive grease (e.g. conductive epoxy, silicone, or ceramic) or an intervening thermally conductive polymer. The intervening layer may be of any material that is both electrically isolative and thermally conductive and may be a compound or mixture of compounds that chemically react when exposed to air, heat, and/or pressure. The thermal interface layer may be, for example, constructed of any material that is both electrically isolative and thermally conductive and may be a compound or mixture of compounds that chemically react when exposed to air, heat, and/or pressure. The intervening layer may comprise multiple layers, such as an electrically isolating layer next to PV cells and a thermally conductive layer next to a heat sink, or may be absent. The layer may be in simultaneous contact with both the photovoltaic cell(s) and the heat sink.

As illustrated in FIG. 8D, both jigs house the heat sink 890, optionally present intervening layer 894, and photovoltaic cell(s) 886 are sandwiched together to allow simultaneous contact of the optionally present intervening layer 894 with the heat sink and the photovoltaic cell(s). Sufficient pressure may be applied to either the upper jig 800, lower jig 840, or both, in a direction toward the photovoltaic components to allow pressure between the cell(s) and the heat sink, and force intimate contact of their surfaces. Because the upper jig is complementary to the housed cell(s) 886, the resulting applied pressure is distributed across the area of a cell-upper jig interface, thus preventing the likelihood of damage to the cell(s). Likewise, because the lower jig is complementary to the housed heat sink, the applied pressure may be less likely to damage the heat sink fins (e.g. crushing or warping the fins). Sufficient heat may also be applied during the process, separately or in conjunction with sufficient pressure, to intimately join the heat sink to the photovoltaic cell(s). This process of temporarily applying pressure and/or heat to unite two or more materials together, also known as laminating, may allow the surface(s) of the cell(s) to more closely contact an adjacent material at a microscopic level and allow increased conductive heat transfer away from the cell(s). A vacuum may be applied to decrease air pressure before, during, and/or after applying pressure and/or heat to aid in removing pockets of air between layers. Removing trapped air may allow a more intimate contact between layers resulting in increased thermal transfer.

Conditions during lamination may vary depending on the photovoltaic tile configuration. In one instance the lamination temperature is approximately 155° C., decreased air pressure is applied for five minutes, and one additional atmosphere of pressure is applied by the jigs to force the heat sink for seven minutes. In another instance, the lamination temperature is between 100° C. and 200° C., or between 125° C. and 175° C., or between 135° C. and 155° C. In another instance 1.25, 1.5, 2, 2.5, 3, 3.5, 4, 4.5, or greater than 5 additional atmospheres of pressure is applied by the jigs to force the heat sink and the photovoltaic cell(s) between the jigs together. In another instance pressure is applied for 1 to 30 minutes, 2 to 20 minutes, 5 to 15 minutes, or greater than 30 minutes. In another instance decreased air pressure is applied for 1 to 30 minutes, 2 to 20 minutes, 5 to 15 minutes, or greater than 30 minutes.

FIG. 8E illustrates a photovoltaic tile following removal of the upper jig and the lower jig. At this stage the laminated heat sink 890 and photovoltaic cell(s) 886 may have a housing fabricated and attached as described above.

The process may comprise additional layers known in the art (e.g. ethyl-vinyl-acetate (EVA), polyester, Tedlar®, EPT) on or within the tile, such as a protective layer (e.g. conformal coating), as described herein.

A vacuum may be used during the process to remove trapped air between the layers.

FIGS. 8F illustrates a variation of FIG. 8A-1 used to construct a photovoltaic tile. The lower jig 840 shown in FIG. 8F may comprise a base depression 850 and a number of frustum cone depressions 861. As with FIG. 8A-1, the base depression 850 and frustum cone depressions 861 may be designed to collectively compliment a heat sink such that the heat sink may be inserted into the lower jig and is incapable of substantial horizontal movement following insertion. The base depression may have a depth 870 roughly the thickness of a heat sink base or slightly less than the thickness of a heat sink base, and a width roughly the same as the heat sink base or slightly larger than the heat sink base. The base depression may be optionally present. Each frustum cone depression 861 may have roughly the same dimensions as the heat sink frustum cone or slightly larger dimensions to allow uninhibited insertion of the heat sink. Vacuum channels (not shown) may be present to provide a vacuum source through the lower jig to the heat sink, as described for the upper jig.

The lamination process for a heat sink comprising frustum cones 891 may be as described above and resulting in a photovoltaic tile as shown in FIG. 8G.

Methods Using Injection Molding

Injection molding techniques commonly known in the field (e.g. screw injection molding) to form a polymeric housing may be used to fabricate a photovoltaic tile. One advantage of injection molding is that a tile may comprise a conductive polymeric housing also acting as a heat sink. Another advantage is that multiple polymeric injections can be made to form different components of the tile where each component may have different polymeric properties. Additionally, injection molding may allow formation of a heat sink that acts as “skin” to coat desired regions of the photovoltaic tile(s) as well as allowing the formation of geometries otherwise not available with traditional fabrication techniques that permit increased convection and cooling.

One or more molds may be generated from e.g. standard machining or electrical discharge machining using any common mold material (e.g. hardened steel, pre-hardened steel, aluminum, or beryllium-copper alloy) to complement the photovoltaic tile design. Photovoltaic cell(s) and wiring may then be positioned within the mold(s) as described above such that one surface of the photovoltaic cell(s) will be ultimately exposed and the remaining surfaces of the photovoltaic cell(s) will be in thermal contact with the polymeric housing upon injection. The mold apparatus is then closed and a heated polymer (e.g. thermally conductive polymer, such as nylon 6-6, and/or a polyphenylene sulfide, optional mixed with one or more metallic fillers; resin; or a fluid-like raw material for injection molding) is channeled into the mold by pressure from e.g. an electric motor or hydraulic source, followed by cooling (e.g. water-channels within the mold) to solidify the tile housing/heat sink. The injected material may be a polymer, mixture of polymers, unpolymerized monomer, mixture of unpolymerized monomers, or any mixture of polymer(s) and unpolymerized monomers(s). The polymer and/or monomer may have a coefficient of thermal expansion that is similar or identical to the coefficient of thermal expansion of the photovoltaic cell(s) to insure intimate contact of the injected material with the photovoltaic cell(s) during temperature changes. High pressure (e.g. 5-6000 tons) and heat applied during the injection process may allow intimate contact between the injection polymer (which may ultimately forms the heat sink) and the photovoltaic cell(s), resulting in increased heat dissipation during operation of the tiles. The mold may then be opened and the tile ejected with assistance of ejector pins within the mold, followed by any necessary machining. The tile is then ready for installation as a roof tile on a roof.

Methods of Installation

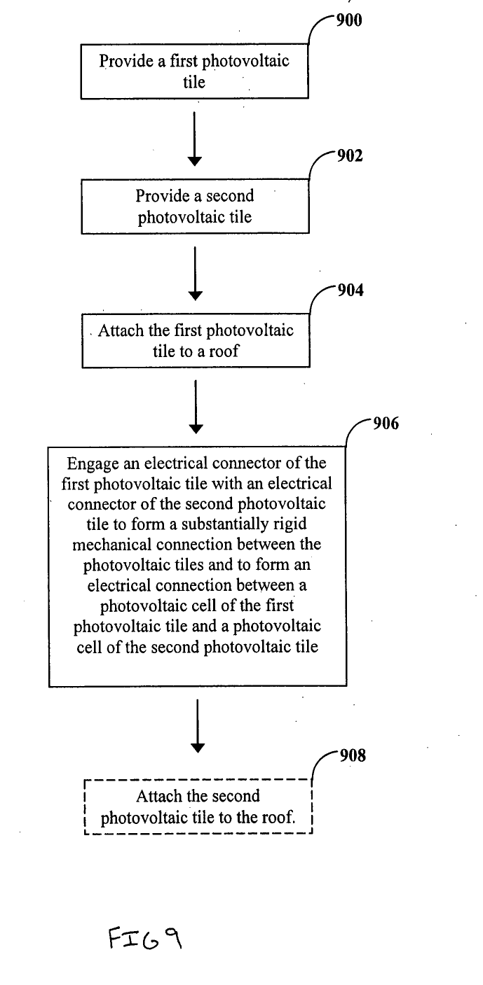

One method of installation is illustrated in FIG. 9. Roof tiles are attached to purlins or battens that retain and support the tiles. Tiles are laid by e.g. nailing the first tile to lowest purlin or batten, engaging male connector of one tile with female connector of a second tile and locking into place by e.g. pushing the two tiles together, nailing the second tile to this purlin or batten, and repeating this across a portion of the roof. The next course of tiles is formed by placing one tile on the next highest purlin or batten so that it partially overlies the tile on the lower purlin or batten, snapping tiles together using the connectors, and nailing tiles to the purlin or batten. The overlapping portions of tiles may be adhered to one another using e.g. bitumen or adhesive to provide a watertight seal and/or prevent the tiles from being lifted by wind.

This process is depicted in the flow chart of FIG. 9. In a step 900, a first photovoltaic tile is provided. In a step 902, a second photovoltaic tile is provided. In a step 904, the first photovoltaic tile is attached to a roof. In a step 906, an electrical connector of the first photovoltaic tile is engaged with an electrical connector of the second photovoltaic tile to form a substantially rigid mechanical connection between the photovoltaic tile and to form an electrical connection between a photovoltaic cell of the first photovoltaic tile and a photovoltaic cell of the second photovoltaic tile. In an optional step 908, the second photovoltaic tile is attached to the roof.

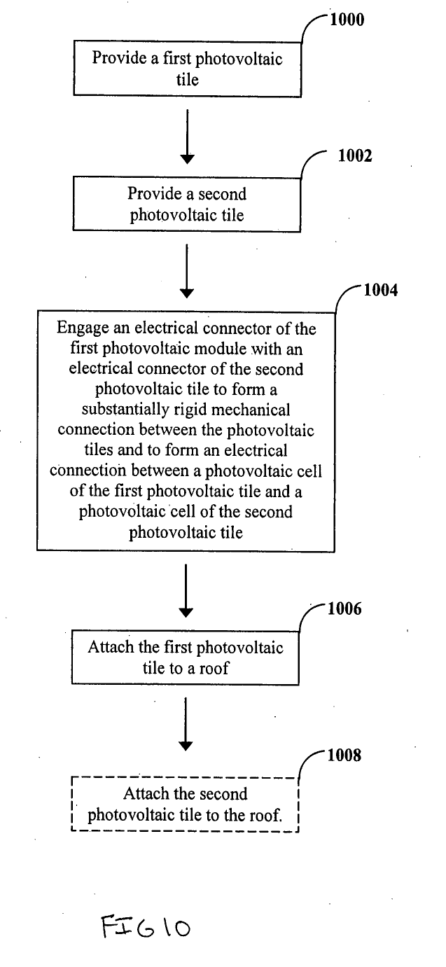

FIG. 10 is a flow chart of a second method for installing a photovoltaic tile. In a step 1000, a first photovoltaic tile is provided. In a step 1002, a second photovoltaic tile is provided. In a step 1004, an electrical connector of the first photovoltaic tile is engaged with an electrical connector of the second photovoltaic tile to form a substantially rigid mechanical connection between the photovoltaic tiles and to form an electrical connection between a photovoltaic cell of the first photovoltaic tile and a photovoltaic cell of the second photovoltaic tile. In a step 1006, the first photovoltaic tile is attached to a roof. In an optional step 708, the second photovoltaic tile is attached to the roof.

In one method of installing photovoltaic roof tiles, plural roof tiles are joined together horizontally through their connectors, parallel to the roofline, and attached on the rooftop at the furthest point from the roofline (closest to ground level). The tiles joined together in this step does not span the entire horizontal length of the rooftop but spans only a portion of the rooftop to provide access on one or both sides of the joined roof tiles. The next vertically adjacent row of roof tiles is then installed, again leaving access on one side or both. This process is repeated until roof tiles cover a section of the roof from the lowest area of the roofline to essentially the highest area of the roofline. The entire process may be repeated to build additional sections of tiles on one or both sides of the completed section. Thus, the horizontal length of individual sections may be short compared to the horizontal length of the rooftop, or the horizontal length of a section may be almost the entire horizontal length of the rooftop. Once all sections of photovoltaic roof tiles have been installed, conventional roof-tiles may be installed along one or both edges of the roof from lowest area of the roofline to highest area to provide areas people may access the rooftop without damaging photovoltaic roof-tiles. In this manner access may be provided to e.g. chimneys and ducts or pipes that penetrate the roof-top. Conventional tiles may be provided near the roofline and near gutters as well if desired.

A tile may be attached individually to the rooftop immediately after it is connected via connectors to an adjacent tile previously secured to the rooftop. Alternatively, multiple tiles may be connected via their connectors, and the assembled tiles may then be secured to the rooftop. For instance, the installer may interconnect many tiles, center the interconnected tiles along the horizontal length of the rooftop, assure the interconnected tiles are also parallel to the roofline, and then secure this first row (furthest from the rooftop) to underlying purlins or battens. The installer may then add tiles individually as described above to finish a section, or the installer may interconnect multiple tiles and connect or overlay them to form the adjacent row of tiles in that section.

The tiles may therefore be installed to complete all or most of a first row of tiles before progressing to form an adjacent row of tiles and so forth until the roof is covered, or the tiles may be installed to form sections that run partially across the horizontal length of the roof and partially or fully to the roofline from near or at the baseline of the roof.

In another instance, a roof may be formed by placing a roofing tile at the baseline of the roof and connecting adjacent tiles by the connectors in a direction toward the roofline. Strips of tiles are formed that can have e.g. a sealing strip or bitumen placed in and/or across the vertically-rising seam formed with adjacent tiles on the left or right of a strip.

The installation process may be performed by placing a roof tile nearest the roofline and then placing rows adjacent in the direction toward the ground in any of the methods discussed above. Any of the tiles described herein may be configured for installation from roofline toward ground or from the portion of the roof closest to ground and toward the roofline. An entire row may be formed or only a portion of a row in either method.

What is claimed is:

1. A photovoltaic tile comprising:
A. a photovoltaic cell,
B. a housing retaining the photovoltaic cell and exposing light-receiving surfaces of the photovoltaic cell along a first surface of the housing,
C. said housing being adapted to mount on a rooftop,
D. a heat sink in thermal communication with an unexposed surface of said photovoltaic cell,
E. said heat sink comprising
i) a base positioned substantially parallel to said unexposed surface, and
ii) a plurality of fins attached to said base positioned substantially parallel to each other,
wherein said base has a thickness between 0.05″ and 0.5″;
wherein said fins each independently have a height between 0.25″ and 7″, a center to center, spacing between 0.05″ and 1″, and a width between 0.001″ and 0.25″;
and wherein the center to center spacing is sufficient to provide a channel between said fins for cooling air to enter.

2. The photovoltaic tile of claim 1, further comprising a thermal interface layer between the heat sink and said unexposed surface to improve heat dissipation.

3. The photovoltaic tile of claim 1, wherein the heat sink has a length, thickness, fin height, fin spacing and fin width to maintain the photovoltaic cell at a temperature below about 150° F. in ambient air at a temperature of 70° F.

4. The photovoltaic tile of claim 1, further comprising an overhang along said first surface of said housing substantially parallel to a ridgeline of the rooftop.

5. The photovoltaic tile of claim 1, further comprising an overhang along said first surface of said housing substantially perpendicular to a ridgeline of the rooftop.

6. The photovoltaic tile of claim 1, wherein the plurality of fins is positioned in a direction substantially parallel to a ridgeline of the rooftop.

7. The photovoltaic tile of claim 1, wherein the plurality of fins is positioned in a direction substantially perpendicular to a ridgeline of the rooftop.

8. The photovoltaic tile of claim 1, wherein the heat sink is constructed of extruded aluminum.

9. The photovoltaic tile of claim 1, wherein the heat sink is constructed of black anodized aluminum.

10. The photovoltaic tile of claim 1, wherein the base is constructed of a conductive polymer.

11. The photovoltaic tile of claim 8, wherein the conductive polymer is an elastomer.

12. The photovoltaic tile of claim 1, wherein said fins are discontinuous along a long axis of said base to form air escape and entry channels.

13. The photovoltaic tile of claim 12, wherein the channels are herringbone shape.

14. The photovoltaic tile of claim 1, wherein said base has a thickness between 0.1″ and 0.25″; and wherein said fins each independently have a height between 0.75″ and 5″, a center to center spacing between 0.2″ and 0.5″, and a width between 0.007″ and 0.1″.

15. The photovoltaic tile of claim 14, further comprising a thermal interface layer between the heat sink and said unexposed surface to improve heat dissipation.

16. The photovoltaic tile of claim 14, wherein the plurality of fins is positioned in a direction substantially perpendicular to a ridgeline of the rooftop.

17. The photovoltaic tile of claim 14, wherein the heat sink is constructed of extruded aluminum.

18. The photovoltaic tile of claim 14, wherein said base has a thickness between 0.1″ and 0.2″; and wherein said fins each independently have a height between 0.9″ and 2″, a center to center spacing between 0.3″ and 0.4″, and a width between 0.02″ and 0.05″.

19. The photovoltaic tile of claim 18, further comprising a thermal interface layer between the heat sink and said unexposed surface to improve heat dissipation.

20. The photovoltaic tile of claim 18, wherein the plurality of fins is positioned in a direction substantially perpendicular to a ridgeline of the rooftop.

21. The photovoltaic tile of claim 18, wherein the heat sink is constructed of extruded aluminum.
